(19) United States
(12) Patent Application Publication
(10) Pub. No.: US 2026/0359617 A1
(43) Pub. Date: Nov. 12, 2026

(54) SURFACE DEFORMATION PREDICTION METHOD, DEVICE, MEDIUM, AND PRODUCT

(71) Applicant: Lanzhou Jiaotong University, Lanzhou City (CN)

(72) Inventors: Xiaoning SU, Lanzhou City (CN); Hui ZHANG, Lanzhou City (CN); Weifang YANG, Lanzhou City (CN); Zufeng LI, Lanzhou City (CN); Yongtai KANG, Lanzhou City (CN); Jiale HUANG, Lanzhou City (CN); Deqiang KONG, Lanzhou City (CN); Guojie MENG, Lanzhou City (CN)

(73) Assignee: Lanzhou Jiaotong University, Lanzhou City, GS (CN)

(21) Appl. No.: 19/452,710

(22) Filed: Jan. 19, 2026

(30) Foreign Application Priority Data
May 7, 2025 (CN) 202510578970.8

(51) Int. Cl. G06N 3/049; G06N 3/08

(52) U.S. Cl. CPC G06N 3/049; G06N 3/08

(57) ABSTRACT

Provided are a surface deformation prediction method, a device, a medium, and a product, relating to the technical field of geological hazard monitoring and surveying. The method includes outputting a cumulative deformation amount in a future period using a trained surface deformation prediction model based on target factors in a study area, where the target factors are data whose influence degree on the cumulative deformation amount in the future period exceeds an influence degree threshold; the target factors include time-series deformation data of historical periods, topographic data of the future period, and environmental data of the future period; the surface deformation prediction model is a model that optimizes weights and bias parameters of a traditional back propagation (BP) neural network using a particle swarm optimization algorithm and a genetic algorithm.

### CROSS REFERENCE TO RELATED APPLICATION

This patent application claims the benefit and priority of Chinese Patent Application No. 2025105789708, filed with the China National Intellectual Property Administration on May 7, 2025, the disclosure of which is incorporated by reference herein in its entirety as part of the present application.

### TECHNICAL FIELD

The present disclosure relates to the technical field of geological hazard monitoring and surveying, and in particular, to a surface deformation prediction method, a device, a medium, and a product.

### BACKGROUND

High-resolution and all-weather monitoring capabilities have made Interferometric Synthetic Aperture Radar (InSAR) technology an important means for surface monitoring. Although InSAR technology can effectively identify the distribution information of surface deformation hazards, it cannot predict the risks of geological disasters that may occur in the future. Neural Network technology, as one of the important technical branches of artificial intelligence, is widely used in surface deformation prediction. Combining time-series InSAR technology with neural network prediction technology can enable early warning, prevention, and control of mining area deformation disasters.

At present, there are many surface prediction model methods using InSAR technology combined with neural networks. However, the problem of insufficient accuracy in predicting surface deformation remains unsolved.

### SUMMARY

An objective of the present disclosure is to provide a surface deformation prediction method, a device, a medium, and a product, which can improve the accuracy of surface deformation prediction.

To achieve the above objective, the present disclosure provides the following technical solutions.

According to a first aspect, the present disclosure provides a surface deformation prediction method, including:
acquiring target factors in a study area, where the target factors are data whose influence degree on a cumulative deformation amount in a future period exceeds an influence degree threshold; the target factors include time-series deformation data of historical periods, topographic data of the future period, and environmental data of the future period; the topographic data includes slope, roughness, and relief, the environmental data includes vegetation coverage and annual average precipitation; and
based on the target factors, outputting the cumulative deformation amount in the future period using a trained surface deformation prediction model, where the surface deformation prediction model is an improved back propagation (BP) neural network; on the basis of a traditional BP neural network, the improved BP neural network is obtained by optimizing weights and bias parameters of the traditional BP neural network by means of a particle swarm optimization (PSO) algorithm and a genetic algorithm (GA).

According to a second aspect, the present disclosure provides a computer device, including: a memory, a processor, and a computer program stored on the memory and executable on the processor, where the processor executes the computer program to implement the surface deformation prediction method according to the first aspect.

According to a third aspect, the present disclosure provides a computer-readable storage medium, where the computer-readable storage medium stores a computer program, and the computer program, when executed by a processor, implements the surface deformation prediction method according to the first aspect.

According to a fourth aspect, the present disclosure provides a computer program product, including a computer program, where the computer program, when executed by a processor, implements the surface deformation prediction method according to the first aspect.

According to specific embodiments provided in the present disclosure, the present disclosure achieves the following technical effects:

The present disclosure provides a surface deformation prediction method, a device, a medium, and a product. The method includes outputting a cumulative deformation amount in a future period using a trained surface deformation prediction model based on target factors in a study area, where the target factors are data whose influence degree on the cumulative deformation amount in the future period exceeds an influence degree threshold; the target factors include time-series deformation data of historical periods, topographic data of the future period, and environmental data of the future period; the surface deformation prediction model is a model that optimizes weights and bias parameters of a traditional BP neural network using a PSO algorithm and a GA. By considering factors such as topography and environment that affect surface deformation, and overcoming the drawback that traditional neural network models are prone to falling into local optima, this application improves the prediction accuracy of the neural network, thereby enabling high-precision surface deformation prediction.

### BRIEF DESCRIPTION OF THE DRAWINGS

To describe the technical solutions in the embodiments of the present disclosure or in the prior art more clearly, the following briefly describes the accompanying drawings required for the embodiments. Apparently, the accompanying drawings in the following description show merely some embodiments of the present disclosure, and a person of ordinary skill in the art may still derive other accompanying drawings from these accompanying drawings without creative efforts.

FIG. 1 is a diagram of an application environment of a surface deformation prediction method according to Embodiment 1 of the present disclosure;

FIG. 2 is a schematic flowchart of a surface deformation prediction method according to Embodiment 1 of the present disclosure, in which 210 denotes Sentinel 1B images, 212 denotes InSAR line-of-sight deformation information, 214 denotes time-series deformation information, 216 denotes selection of surface deformation driving factors by combining a geographical detector with data factor discretization, 218 denotes factors such as topography and environment, 220 denotes construction of a GA-PSO-BP prediction model based on the surface deformation driving factors, 222 denotes comparison of prediction accuracy with existing GA-BP and PSO-BP models using InSAR observation data, and 224 denotes construction of an integrated final model for surface deformation monitoring and prediction;

FIG. 3 is a schematic diagram of an InSAR line-of-sight deformation field according to Embodiment 1 of the present disclosure;

FIGS. 4A-4C are comparative diagrams of four discretization methods for example detection factors according to Embodiment 1 of the present disclosure;

FIG. 5 is a schematic diagram illustrating detection results of the influence of single factors on surface deformation in Embodiment 1 of the present disclosure;

FIG. 6 is a schematic diagram illustrating detection results of the influence of factor interactions on surface deformation in Embodiment 1 of the present disclosure;

FIGS. 7A-7B are schematic diagrams illustrating comparison between predicted and actual results along with fitting results in Embodiment 1 of the present disclosure; and

FIG. 8 is a schematic structural diagram of a computer device according to Embodiment 2 of the present disclosure, in which 800 denotes the computer device, 801 denotes a processor, 802 denotes an internal memory, 803 denotes a non-volatile storage medium, 804 denotes an input/output interface, 805 denotes a communication interface, and 806 denotes a system bus.

### DETAILED DESCRIPTION OF THE EMBODIMENTS

The technical solutions in the embodiments of the present disclosure are clearly and completely described below with reference to the drawings in the embodiments of the present disclosure. Apparently, the described embodiments are only some rather than all of the embodiments of the present disclosure. All other embodiments obtained by a person of ordinary skill in the art based on the embodiments of the present disclosure without creative efforts shall fall within the protection scope of the present disclosure.

To make the above objectives, features, and advantages of the present disclosure more obvious and easy to understand, the present disclosure will be further described in detail with reference to the accompanying drawings and specific implementations.

### Embodiment 1

Research has found that in current surface prediction model methods combining InSAR technology with neural networks, traditional neural networks are prone to falling into local optima and are sensitive to initial weights and biases. In addition, the prediction model only utilizes time-series InSAR monitoring data, without considering the influence of environmental factors such as precipitation and terrain on surface deformation.

In view of this, this embodiment proposes a surface deformation prediction method that integrates InSAR technology with a GA-PSO-BP neural network. This method directly optimizes the basic network parameters, thereby avoiding the overfitting problem caused by redundant convolutional kernels in convolutional neural network (CNN), and is more suitable for the high-precision prediction requirements of small-sample coal mine data. This method utilizes a geodetector to select a time-series deformation and environmental factor dataset, integrates the global search capability and fast convergence advantages of the GA and PSO, constructs a surface deformation prediction model for mining areas, and achieves high-precision surface deformation prediction.

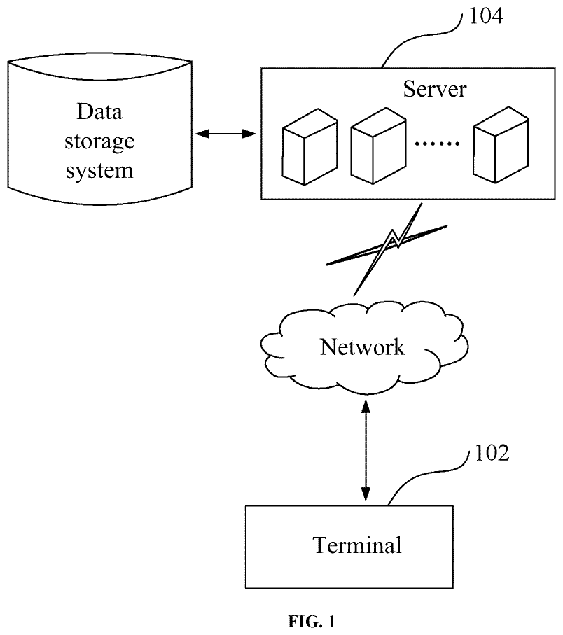

The surface deformation prediction method provided by the embodiment of the present disclosure can be applied in an application environment as shown in FIG. 1. A terminal 102 communicates with a server 104 via a network. A data storage system can store data that the server 104 needs to process. The data storage system can be independently set up, integrated with the server 104, or placed in the cloud or on other servers. The terminal 102 can send target factors of a study area to the server 104. After receiving the target factors, the server 104, based on the target factors, outputs a cumulative deformation amount in a future period using a trained surface deformation prediction model, where the surface deformation prediction model is an improved BP neural network. On the basis of a traditional BP neural network, the improved BP neural network is obtained by optimizing weights and bias parameters of the traditional BP neural network by means of a PSO algorithm and a GA. The server 104 can feed back the obtained cumulative deformation amount of the future period to the terminal 102. Furthermore, in some embodiments, the surface deformation prediction method can also be implemented solely by the server 104 or the terminal 102. For example, the terminal 102 can directly process the target factors in the study area using the surface deformation prediction method, or the server 104 can obtain the target factors in the study area from the data storage system and process the target factors using the surface deformation prediction method.

The terminal 102 can be, but is not limited to, various desktop computers, laptops, smartphones, tablets, Internet of Things (IoT) devices, and portable wearable devices. The IoT device may be a smart speaker, a smart TV, a smart air conditioner, a smart in-vehicle device, or the like. The portable wearable device can be a smart watch, a smart band, a head-mounted device, or the like. The server 104 can be implemented using a standalone server, a server cluster consisting of a plurality of servers, or a cloud server.

This embodiment provides a surface deformation prediction method. The method is executed by a computer device. Specifically, the method can be executed solely by a computer device such as a terminal or a server, or jointly by a terminal and a server. In the embodiment of the present disclosure, the method is described as being applied to the server 104 in FIG. 1, and includes the following step 201 to step 202. Specifically:
Step 201: Acquire target factors in a study area, where the target factors are data whose influence degree on a cumulative deformation amount in a future period exceeds an influence degree threshold; the target factors include time-series deformation data of historical periods, topographic data of the future period, and environmental data of the future period; the topographic data includes slope, roughness, and relief, the environmental data includes vegetation coverage and annual average precipitation.
Step 202: Based on the target factors, output the cumulative deformation amount in the future period using a trained surface deformation prediction model, where the surface deformation prediction model is an improved BP neural network; on the basis of a traditional BP neural network, the improved BP neural network is obtained by optimizing weights and bias parameters of the traditional BP neural network by means of a PSO algorithm and a GA.

A training process of the surface deformation prediction model specifically includes:
(a) acquiring a sample dataset, where the sample dataset includes historical sample radar image sequences, historical sample topographic time-series data, and historical sample environmental time-series data;
(b) processing the historical sample radar image sequences using remote sensing technology to obtain InSAR line-of-sight historical time-series deformation data;
(c) processing the InSAR line-of-sight historical time-series deformation data, the historical sample topographic time-series data, and the historical sample environmental time-series data using a discretization method to obtain a preprocessed dataset;
(d) calculating contribution intensities by using the preprocessed dataset as independent variables and a historical cumulative deformation amount as a dependent variable, wherein the historical cumulative deformation amount is a variable value calculated based on the InSAR line-of-sight historical time-series deformation data; the contribution intensities include a contribution intensity of each independent variable to the dependent variable and contribution intensities of interactions between the independent variables to the dependent variable; and
(e) training the surface deformation prediction model by using independent variables whose contribution intensities are greater than a contribution intensity threshold as feature data and using the historical cumulative deformation amounts as label data.

To make the above process of this embodiment clearer to those skilled in the art, the following provides a detailed explanation.

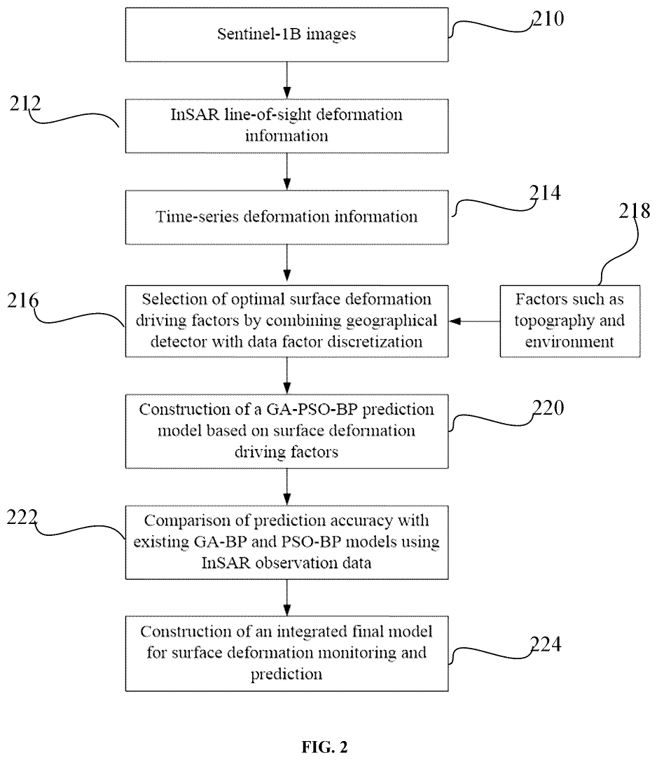

Existing models for small-sample coal mining areas inadequately quantify the contribution of complex environmental factors and have limited generalization capability under small-sample conditions, making it difficult to meet the needs of high-precision prediction in small-sample areas. To address this shortcoming, this embodiment, considering data characteristics of small-sample coal mining areas, provides a surface deformation prediction method that integrates InSAR observation data with neural networks. The method includes four parts: calculation of an InSAR line-of-sight direction, selection of optimal surface deformation driving factors, GA-PSO-BP prediction, and analysis and validation, as shown in FIG. 2. Specifically, the method includes:

### I. Calculation of an InSAR Line-of-Sight Deformation Field

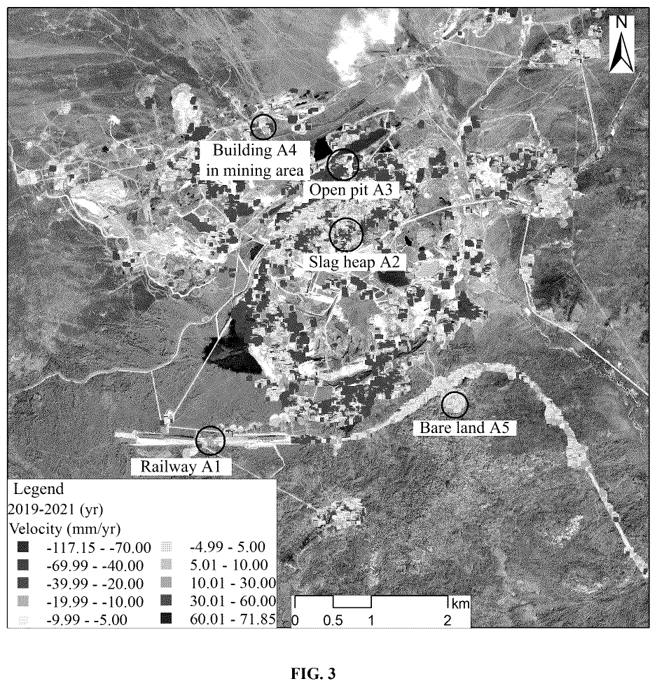

S1: Perform time-series processing on InSAR data (the InSAR data in this embodiment is a Sentinel-1B radar image sequence) by using a Small Baseline Subset InSAR (SBAS-InSAR) method to obtain an InSAR line-of-sight time-series deformation field (namely, the InSAR line-of-sight historical time-series deformation data). This step is specifically implemented as follows:
1. Based on a preset spatiotemporal baseline coherence threshold, baseline screening is performed on the InSAR data to obtain a plurality of image pairs that satisfy the constraints of the spatiotemporal baseline coherence threshold. Specifically, a master image is screened from the acquired images through baseline estimation. Jul. 4, 2020 is selected as a common master image; a temporal baseline coherence threshold is set to 240 days, and the length of a spatial baseline coherence threshold is set to 45% of the total length.
2. The image pairs that meet the constraints of the spatiotemporal baseline coherence threshold are grouped to obtain a plurality of small baseline subsets.
3. Multi-looking processing is performed on the small baseline subsets to obtain multi-looked baseline subsets. A multi-look ratio in this embodiment is set to 4:1, and the role of multi-looking is to reduce noise.
4. Interference phase filtering is performed on the multi-looked baseline subsets by using the Goldstein adaptive filtering algorithm, to generate filtered baseline subsets.
5. Phase unwrapping is performed on the filtered baseline subsets using minimum cost flow (MCF), to generate an unwrapped phase matrix. An unwrapping coherence threshold in this embodiment is set to 0.25 (only high-coherence areas are retained).
6. The unwrapped phase matrix is mapped to a time benchmark of the common master image to construct a small baseline subset phase observation equation.
7. Singular value decomposition (SVD) and reconstruction are performed on an overall observation equation combining all small baseline subset phase observation equations, deformation phase components of each subset and time-series constraints are jointly inverted, and the reconstructed observation equation is iteratively solved using a weighted least squares method, to obtain a millimeter-level time-series deformation field in the radar line-of-sight (LOS) (that is, InSAR line-of-sight historical time-series deformation data), as shown in FIG. 3.

### II. Selection of Optimal Surface Deformation Driving Factors

S2: Perform down-sampling processing on the InSAR line-of-sight historical time-series deformation data in S1, and calculate topographic and environmental factor values (that is, values corresponding to the historical sample topographic time-series data and historical sample environmental time-series data) at sampling points.

The InSAR line-of-sight historical time-series deformation data is down-sampled and filtered to 5140 points. Considering the influence of factors such as topography and environment on the surface cumulative deformation y (namely, the historical cumulative deformation amount), this example selects elevation (X1), slope (X2), aspect (X3), plan curvature (X4), roughness (X5), relief (X6), vegetation coverage (X7), annual average precipitation (X8), annual average surface deformation rate (X9), and 10 time-series deformations (X10-X19) as driving factors x. Based on this, the topographic and environmental factor values at the sampling points are calculated.

The slope (X2), aspect (X3), plan curvature (X4), roughness (X5), and relief (X6) factors are all calculated from elevation (X1). Vegetation coverage (X7) is calculated from Sentinel-2 images. Annual average precipitation data is sourced from the China Meteorological Network. The time-series deformations are the InSAR line-of-sight historical time-series deformation data described in S1. The surface cumulative deformation is a variable calculated based on the InSAR line-of-sight historical time-series deformation data described in S1. The specific calculation methods for each factor are as follows:

$$X 2 = arc tan ( \sqrt{{( \frac{\partial w}{\partial u} )}^{2} + {( \frac{\partial w}{\partial v} )}^{2}} ) ;$$

$$X 3 = arc tan ( \frac{\frac{\partial w}{\partial v}}{\frac{\partial w}{\partial u}} ) ;$$

$$X 4 = \frac{\frac{{\partial }^{2} w}{\partial {u}^{2}} {( \frac{\partial w}{\partial v} )}^{2} + \frac{{\partial }^{2} w}{\partial {v}^{2}} {( \frac{\partial w}{\partial u} )}^{2} - 2 \frac{{\partial }^{2} w \partial w \partial w}{\partial u \partial v \partial u \partial v}}{{( {( \frac{\partial w}{\partial u} )}^{2} + \frac{\partial {w}^{2}}{\partial v} )}^{3 / 2}} ;$$

$$X 5 = \sqrt{\frac{1}{n} {\sum }_{i = 1}^{n} {( {w}_{i} - \overline{w} )}^{2}} ;$$

$$X 6 = max ( {w}_{i} ) - min ( {w}_{i} ) ;$$

$$X 7 = \frac{NDVI - {NDVI}_{min}}{{NDVI}_{max} - {NDVI}_{min}} ;$$

$$NDVI = \frac{NIR - Red}{NIR + Red} ;$$

In the formulas, w represents an altitude (elevation value) of a specific point; u and v represent plane coordinates of the point, specifically the east-west direction and the north-south direction, respectively;

$$\frac{\partial w}{\partial u} and \frac{\partial w}{\partial v}$$

are gradients of the elevation in the east-west direction and the north-south direction, respectively; wᵢ is an elevation value of each pixel in a local area; w̅ is an average elevation of the local area; n is a total number of pixels in the local area; NDVI is a normalized difference vegetation index; NDVIₘᵢₙ is a minimum value of the normalized difference vegetation index; NDVIₘₐₓ is a maximum value of the normalized difference vegetation index; NIR is a near-infrared band; Red is a red band.
S3: Use the sampling points obtained in S2 as fundamental data for geographic detection.

The time-series deformations and the topographic and environmental factor values described in S2 are used as independent variables, and the surface cumulative deformation is used as a dependent variable, to prepare fundamental data for driving factor detection.

Since the manual grading of factor values in traditional geodetectors can easily lead to data distortion, this embodiment first processes the aforementioned independent variables using a discretization method. The discretization method converts continuous geographic factors (such as slope and elevation) into discrete categories, reducing noise interference and enhancing the model's ability to capture nonlinear relationships. This approach can achieve the following advantages: 1) Mitigate the curse of dimensionality: Continuous variables in small samples easily cause model overfitting, while discretization can compress the feature space. 2) Enhance feature separability: Coal mine deformation often exhibits threshold effects (for example, landslide risk increases sharply when the slope exceeds a particular value); discretization can highlight such segmented patterns. 3) Reduce subjective bias: Traditional manual division (for example, fixed thresholds) may overlook local geological characteristics of the coal mine; automated discretization (such as a natural breaks method) can implement adaptive classification based on the data distribution.

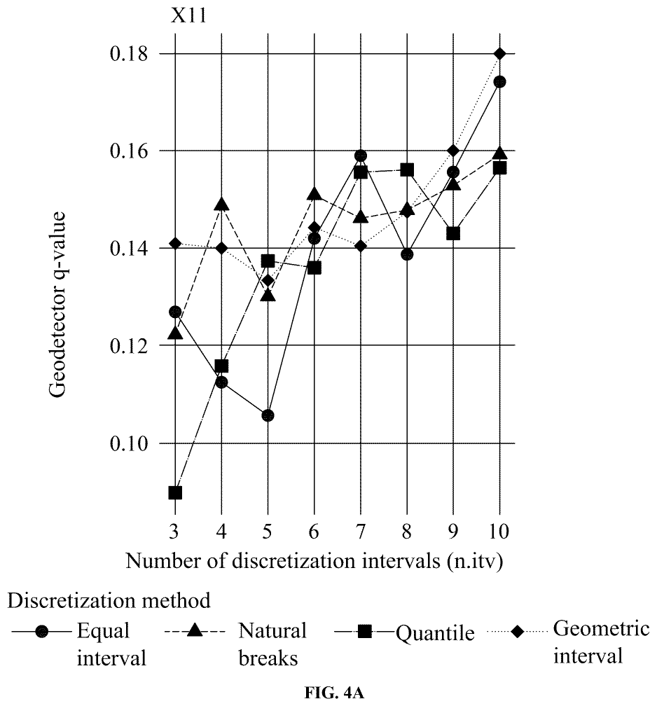

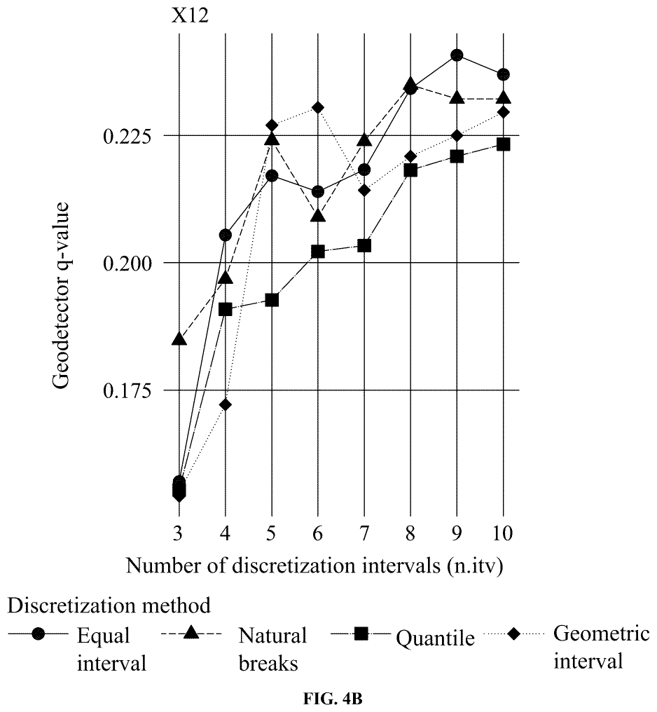

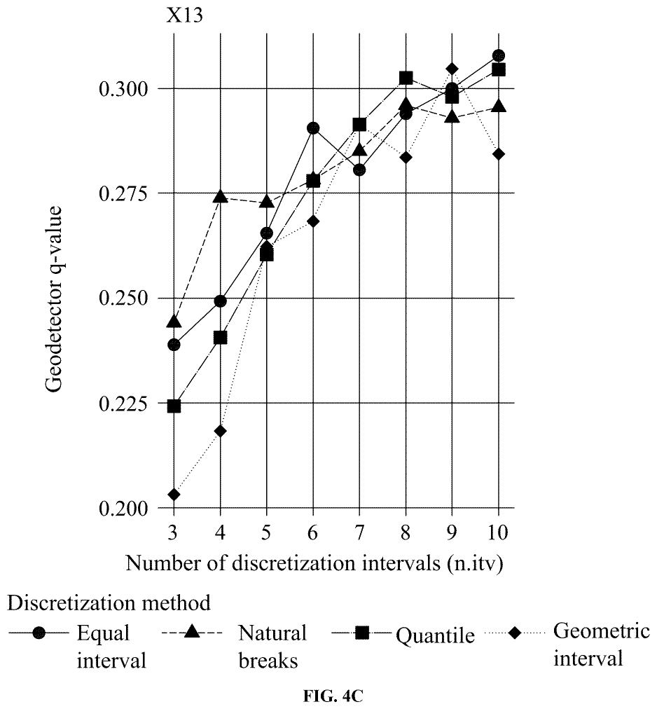

The discretization method in this embodiment includes an equal interval method, a natural breaks method, a quantile method, and a geometric interval method. As shown in FIGS. 4A-4C, four discretization methods are used to process the independent variables X11-X13. The expression corresponding to the equal interval method is:

$${X}_{E 1} = min ( {D}_{1} ) + ( \frac{max ( {D}_{1} ) - min ( {D}_{1} )}{{K}_{1}} ) \times i ( i = 1 , 2 , … , {K}_{1} - 1 ) ;$$

where X_{E1} represents a value of an i-th breakpoint; i is an integer from 1 to K₁−1, representing a breakpoint sequence number; D₁ is an original dataset; K₁ is a preset number of groups; max(D₁) and min(D₁) are a maximum data value and a minimum data value, respectively.

The expression corresponding to the natural breaks method is:

$${S}_{2} = {\sum }_{m = 1}^{{K}_{2}} {\sum }_{y ∈ {G}_{m 2}} {( y - {μ}_{m 2} )}^{2} ;$$

where S₂ is a sum of within-group variances; m represents a group sequence number; y is a single data value belonging to an m-th group Gₘ₂; Gₘ₂ is a dataset of the m-th group; μₘ₂ is a mean of data in the m-th group.

The expression corresponding to the quantile method is:

$${X}_{Q 3} = Quantile ( {D}_{3} , \frac{a}{{K}_{3}} ) ( a = 1 , 2 , … , {K}_{3} - 1 ) ;$$

where X_{Q3} represents a value of an a-th breakpoint; a is an integer from 1 to K₃−1, representing a breakpoint sequence number; D₃ is an original dataset; K₃ is a preset number of groups; Quantile

$$( {D}_{3} , \frac{a}{{K}_{3}} )$$

is a-th quantile of dataset D₃.

The expression corresponding to the geometric interval method is:

$${X}_{G 4} = min ( {D}_{4} ) \times {( \frac{max ( {D}_{4} )}{min ( {D}_{4} )} )}^{b / {K}_{4}} ( b = 1 , 2 , … , {K}_{4} - 1 ) ;$$

where X_{G4} represents a value of a b-th breakpoint; b is an integer from 1 to K₄−1, representing a breakpoint sequence number; D₄ is an original dataset; K₄ is a preset number of groups; max(D₄) and min(D₄) are a maximum data value and a minimum data value, respectively.
S4: Perform, by using a geodetector, driving factor detection on the fundamental data obtained after discretization processing in S3, to obtain contribution intensities of each driving factor and factor interactions to the surface cumulative deformation, and determine an optimized set of surface deformation driving factors based on the contribution intensities.

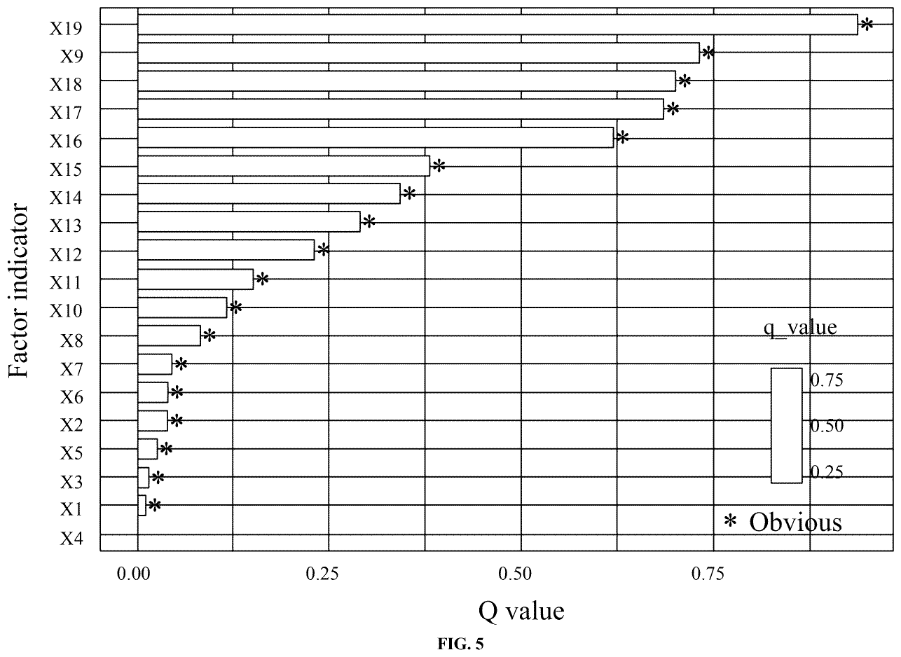

The geodetector is used to detect the driving effect of each independent variable on the dependent variable, including detecting single-factor influence and factor interactions, ultimately selecting the optimal driving factors. The factor detector is used to analyze the degree of influence of each independent variable on the spatial distribution formation of the dependent variable, identifying the driving force magnitude of different driving factors on the spatial distribution of the dependent variable. The expression is as follows:

$$q = 1 - \frac{{\sum }_{h = 1}^{L} {N}_{h} {σ}_{h}^{2}}{N {σ}^{2}} ;$$

where h is the number of stratifications of driving factor x, h=1, 2, . . . , L; N and σ² are a total number of units in the entire area and a variance of y values, respectively; q is a driving force metric value, falling in a range of [0,1]; a larger value of q indicates a stronger driving force of factor x on dependent variable y, and a smaller value of q indicates a weaker driving force of factor x on dependent variable y. The results of single-factor detection are shown in FIG. 5.

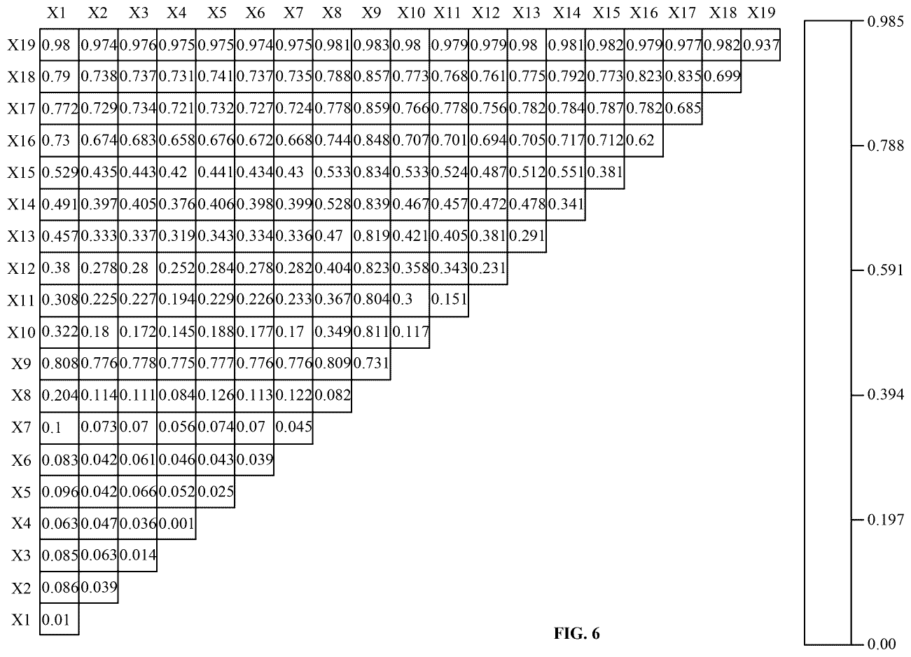

Interaction detection is used to detect the degree of influence of two different influencing factors on the surface cumulative deformation under their combined action. The specific process includes: separately calculating the q values of the two influencing factors X1 and X2 through factor detection; then, calculating q(X1∩X2) under the interaction of X1 and X2, and determining an interaction relationship between X1 and X2 by comparing q(X1), q(X2), and q(X1∩X2) (Table 1). The detection results of interactions between factors are shown in FIG. 6.

TABLE 1
Driving Factor Interaction Determining Methods and Interaction Relationships

| Determining method | Interaction relationship |
|---|---|
| q(X1∩X2) < Min(q(X1), q(X2)) | Nonlinear weakening |
| Min(q(X1), q(X2)) < q(X1∩X2) < Max(q(X1), q(X2)) | Single-factor nonlinear weakening |
| q(X1∩X2) > Max(q(X1), q(X2)) | Bi-factor enhancement |
| q(X1∩X2) = q(X1) + q(X2) | Independent |
| q(X1∩X2) > q(X1) + q(X2) | Nonlinear enhancement |

The driving factors selected in this embodiment include natural characteristic factors X2, X5, X6, X7, and X8, and deformation factors X9 to X19, totaling 16 factors, to proceed with subsequent prediction.

III. Surface Deformation Prediction (that is, GA-PSO-BP Prediction)
S5: By taking the driving factor set (16 factors) described in S4 as input and the surface cumulative deformation as labels, set reasonable GA-PSO-BP neural network thresholds, compare with traditional GA-BP and PSO-BP, establish an optimal prediction model, and predict the surface cumulative deformation.

The implementation of the GA-PSO-BP neural network involves the following key steps: First, the driving factor set described in S4 is divided into a training and a test set at a ratio of 7:3, and the dataset is preprocessed and normalized to ensure the quality and consistency of input data. Second, the weights and biases of the neural network are initialized to provide a foundation for the optimization process. Next, parameters of the GA and PSO algorithms are configured, including population size, crossover probability, mutation probability, and inertia weight, to establish initial settings. Finally, parameters are defined for each layer of the GA and PSO algorithms to enable seamless integration and optimization within the framework of the neural network. The GA and PSO algorithms are used to optimize the parameters of the neural network (Table 2).

TABLE 2
Parameter Configuration for Each Layer of the GA and PSO Algorithms

| Parameter name | Value | Description |
|---|---|---|
| Maximum generations | 50 | Maximum number of iterations for the algorithm |
| Population size | 5 | Number of individuals in the algorithm |
| Learning factor | 4.949 | Controls the balance between individual learning |
| | | and group learning |
| Maximum velocity | 1.0 | Maximum speed of individual movement |
| Minimum velocity | −1.0 | Minimum speed of individual movement |
| Maximum boundary | 1.0 | Upper limit of the search space |
| Minimum boundary | −1.0 | Lower limit of the search space |

Detailed steps of the optimization process are as follows:
a. Optimize weights and bias parameters of the neural network by using the GA and PSO algorithms. The optimized weights and biases are represented by the following formulas:

$${W}_{1}^{*} = reshape ( {Θ}_{1}^{1 : n . h} , h , n ) ;$$

$${B}_{1}^{*} = {Θ}_{2}^{1 : h} ;$$

$${W}_{2}^{*} = reshape ( {Θ}_{3}^{1 : h - o} , o , h ) ;$$

$${B}_{2}^{*} = {Θ}_{4}^{1 : o} ;$$

where

$${W}_{1}^{*} and {W}_{2}^{*}$$

represent a weight matrix from an input layer to a hidden layer and a weight matrix from the hidden layer to an output layer, respectively;

$${B}_{1}^{*} and {B}_{2}^{*}$$

represent bias vectors for the hidden layer and the output layer, respectively; Θ represents a complete set of all parameters; n, h, and o represent the number of nodes in the input layer, the number of nodes in the hidden layer, and the number of nodes in the output layer, respectively. The reshape function is used to reorganize the parameter vector into a two-dimensional shape suitable for the weight matrix.
b. Calculate output of the neural network and an error, and use an error function (mean squared error) to evaluate the performance of the neural network. An evaluation metric can be expressed as:

$$Fitness = \frac{1}{n} {\sum }_{i = 1}^{n} {( {t}_{i} - {a}_{i} )}^{2} ;$$

where Fitness is a fitness function; tᵢ is a network output value for an i-th training sample; aᵢ is an expected output value for the i-th training sample; n is the number of training samples.
c. Update populations or particles of the GA and PSO algorithms according to the value of the error function to gradually optimize the parameters of the neural network. The population with the best fitness is directly copied into the next generation. For the population with moderate fitness, two particles are randomly selected for a crossover operation with crossover probability Pc, and an optimal individual is selected. For the population with poorer fitness, a mutation operation is performed with mutation probability Pm. A crossover operation is performed on the velocities of particle i and particle j:

$$\{ \begin{matrix}{v}_{i} ( t + 1 ) = {θ}_{1} {v}_{i} ( t ) + ( 1 - {θ}_{1} ) {v}_{j} ( t ) \\ {v}_{j} ( t + 1 ) = ( 1 - {θ}_{1} ) {v}_{i} ( t ) + {θ}_{1} {v}_{j} ( t )\end{matrix} ;$$

$$\{ \begin{matrix}{x}_{i} ( t + 1 ) = {θ}_{2} {x}_{i} ( t ) + ( 1 - {θ}_{2} ) {x}_{j} ( t ) \\ {x}_{j} ( t + 1 ) = ( 1 - {θ}_{2} ) {x}_{i} ( t ) + {θ}_{2} {x}_{j} ( t )\end{matrix} ;$$

where θ₁ and θ₂ are random values within a range of [0,1], used to control the proportion of velocity and position crossover, respectively; vᵢ(t) and xᵢ(t) represent the velocity and position of particle i at iteration step t; vⱼ(t) and xⱼ(t) are the corresponding velocity and position values of another randomly selected particle j. The new velocity and position generated for particle i through the crossover operation are denoted as vᵢ(t+1) and xᵢ(t+1). The new velocity and position generated for particle j through the crossover operation are denoted as vⱼ(t+1) and xⱼ(t+1). The fitness values of the offspring particles after the crossover operation are compared with the fitness values of the parent particles, and the particles with larger fitness values are retained for the next iteration.
d. Repeat the aforementioned steps until the following termination conditions are met: when the number of iterations reaches a preset maximum value, or when an algorithm error falls below a specific threshold.

### IV. Result Analysis and Validation

S6: Evaluate the accuracy of prediction results.

To evaluate the prediction performance of the model, root mean squared error (RMSE) and mean absolute error (MAE) are selected as indicators to assess the prediction performance of the model. The calculation methods for the RMSE and MAE are as follows:

$$RMSE = \sqrt{\frac{1}{n} {\sum }_{i = 1}^{n} {( {y}_{i} - {\hat{y}}_{i} )}^{2}} ;$$

$$MAE = \frac{1}{n} {\sum }_{i = 1}^{n} \vert {y}_{i} - {\hat{y}}_{i} \vert ;$$

where n is a total number of samples, yᵢ is an InSAR monitored value, and ŷᵢ is a predicted value.

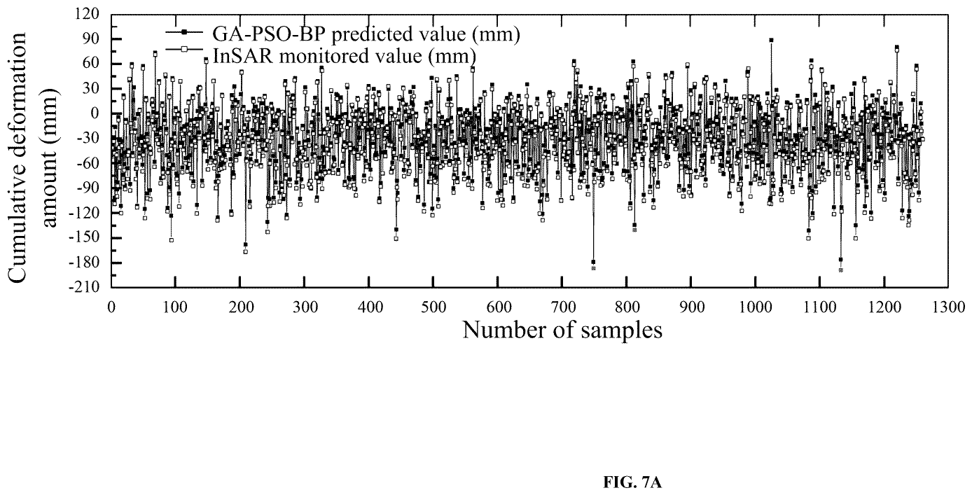

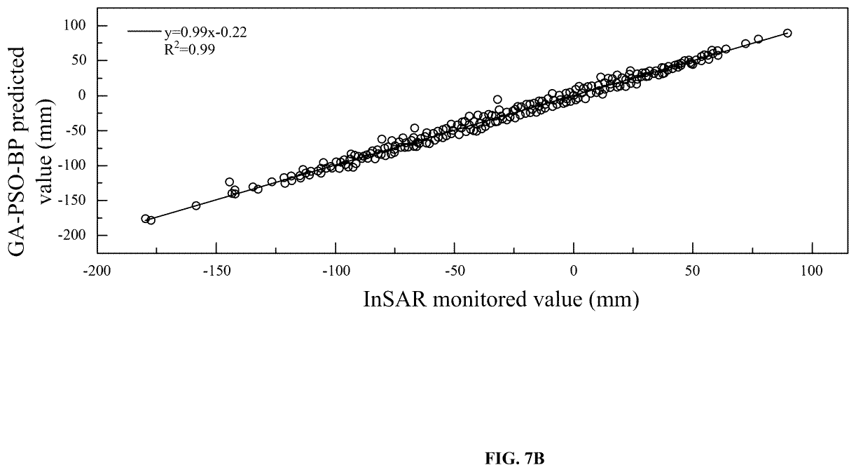

GA-BP, PSO-BP, and GA-PSO-BP are used to generate prediction results, and the RMSE and MAE of the three prediction results are calculated. As can be seen from Table 3, the coefficient of determination R² of both the training set and test set of the three models reaches 0.99, indicating that all three models exhibit strong fitting capabilities. In terms of error indicators, the GA-PSO-BP model performs slightly better than the GA-BP and PSO-BP models in terms of RMSE and MAE. The RMSE of the test set is 2.68 mm and the MAE is 2.01 mm, indicating its high prediction accuracy. Fitting the predicted values with the InSAR monitored values (FIGS. 7A-7B) shows that the coefficient of determination R² between the two reaches 0.99, indicating a high correlation. Therefore, the GA-PSO-BP prediction model based on time-series InSAR technology has good reliability in deformation research in mining areas.

TABLE 3
Comparison Results of Accuracy for Three Prediction Models

| | Root mean squared | | |
|---|---|---|---|
| | error (RMSE) | Mean absolute error | Coefficient of |
| Neural network | Training | (MAE) | determination (R²) |

| type | set | Test set | Training set | Test set | Training set/test set |
|---|---|---|---|---|---|
| GA-BP | 3.39 | 3.62 | 2.52 | 2.58 | 0.99 |
| PSO-BP | 3.54 | 3.54 | 2.62 | 2.64 | 0.99 |
| GA-PSO-BP | 2.76 | 2.68 | 2.15 | 2.01 | 0.99 |

This embodiment proposes a surface deformation prediction method combining InSAR observation data and neural network. It can not only obtain a high-precision surface deformation field but also construct a GA-PSO-BP prediction model (that is, surface deformation prediction model) that integrates the advantages of the global search capability of the GA and the fast convergence of PSO after considering the driving factors of surface deformation.
(1) Addressing the issue where previous deformation predictions only used historical deformation data to forecast future deformation without considering factors such as topography and environment that affect surface deformation, this embodiment uses a geodetector with optimal parameters after discretization to quantitatively analyze the driving factors of surface deformation in mining areas, selects optimal driving factors, and performs surface deformation prediction based on InSAR deformation data and driving factors, thereby enhancing the scientificity and reliability of the prediction model.
(2) Addressing the issue where traditional neural network prediction methods have slow convergence speeds and are prone to falling into local optima, this embodiment employs the GA-PSO-BP prediction model that combines the advantages of the global search capability of the GA algorithm and the fast convergence of PSO, to improve the prediction accuracy and convergence speed of the BP neural network and overcome the tendency to fall into local optima. A high-precision surface prediction model is constructed.
(3) By comparatively analyzing the prediction effects of GA-BP and PSO-BP optimization algorithms, a surface deformation prediction model with higher accuracy and stronger robustness is constructed, providing key technical support for deformation monitoring and early warning in mining areas.

The particularity of small-sample coal mining area data is taken into consideration.
1. This embodiment addresses the problem of data scarcity (where the data scarcity refers to that coal mining areas often have limited sample sizes due to high monitoring costs, insufficient historical records, or sudden disasters, making traditional big-data-driven models prone to overfitting) through joint dimensionality reduction using the geodetector and discretization methods, and by improving the sample efficiency with an enhanced neural network.

Specifically, the geodetector quantifies the explanatory power of each factor (such as slope and precipitation) on deformation, automatically screens key influencing factors, eliminates redundant features, and reduces the curse of dimensionality under small-sample conditions.

Four discretization methods (equal interval/natural breaks/quantile/geometric interval) convert continuous variables into categorical variables, compressing the feature space and reducing the model's demand for sample size.

Traditional BP networks are prone to overfitting under small-sample conditions, while PSO-GA collaborative optimization intelligently searches for weights/biases, avoiding the reliance of gradient descent methods on large amounts of iterative data.
2. This embodiment addresses the problems of nonlinearity and spatial heterogeneity (where nonlinearity refers to that coal mine deformation is influenced by the coupling of multiple factors such as goaf subsidence and groundwater extraction, resulting in highly nonlinear data characteristics; spatial heterogeneity refers to that geological structures in coal mines vary significantly, and deformation patterns in local areas may differ markedly) through the collaborative input of multi-source target factors and the enhancement of nonlinear expression via discretization.

Specifically, by simultaneously inputting time-series deformation data (historical subsidence patterns), topographic data, and environmental data, the model's ability to model complex mechanisms is enhanced through multimodal data complementarity.

Discretization transforms continuous nonlinear relationships into piecewise linear relationships, enabling even simple neural networks to fit complex patterns.
3. This embodiment addresses the problem of temporal instability (where temporal instability refers to that phased mining activities cause sudden changes in deformation rates, making it difficult for small samples to cover all operating conditions) through dynamic encoding of historical deformation data and optimization of anti-disturbance performance via PSO-GA.

Specifically, using historical time-series deformation data as input factors allows the neural network to implicitly learn temporal dependencies, avoiding the strict requirements of traditional time-series models on small-sample time-series lengths.

The swarm intelligence of PSO and the mutation mechanism of GA enable the model to cover more potential solution spaces during parameter search, maintaining robustness even when outliers caused by sudden changes in mining activities exist in the samples.

In summary, this embodiment addresses the issue of factor representation distortion under small-sample conditions through automated discretization, and overcomes the local optimal limitations of traditional neural networks by using hybrid intelligent optimization, ultimately achieving the deformation prediction requirement of “few data, high precision” in coal mining scenarios.

Compared with the prior art, this embodiment has the following advantages:

Improved prediction accuracy: Through the combined optimization of GA and PSO, the prediction accuracy of the BP neural network is enhanced, with the RMSE of the test set reduced to 2.68 mm and the MAE reduced to 2.01 mm.

Scientific screening of key factors: The geodetector method with optimal parameters after discretization is used to quantify driving factors, reducing factor data distortion and ensuring the scientificity and reliability of model inputs.

Enhanced model robustness: Through comparative analysis, the GA-PSO-BP model demonstrates superior fitting capability and stability compared to the GA-BP and PSO-BP models.

High practical application value: The research results validate the effectiveness of the prediction model in surface deformation monitoring and early warning, providing important technical support for the early prevention of surface hazards.

This embodiment addresses the special complexity of surface deformation in coal mining areas caused by the multi-scale coupling effect of mining disturbances and topographic environmental factors (for example, slope changes affect stress distribution, precipitation infiltration exacerbates fracture development, and vegetation coverage reflects surface stability). The traditional BP neural network, with its fully connected structure, is more suitable for processing low-dimensional time-series and environmental feature data, but it is limited by the risk of overfitting under small-sample conditions and the local convergence characteristics of traditional BP algorithms, making it difficult to achieve reliable generalization performance. The surface deformation prediction model uses GA for global optimization on the initial weights of the neural network and PSO for dynamic optimization of the network bias parameters. It not only retains the architectural advantages of the BP neural network in processing low-dimensional time-series and environmental feature data but also significantly improves the convergence and generalization ability of the model under small-sample conditions. Meanwhile, addressing the difficulty of quantifying factor contribution due to scarce mining area data, a geographical detector is adopted to integrate multiple discretization methods to realize adaptive optimization of classification thresholds, which effectively overcomes the subjective influence of traditional manual reclassification and reduces factor data distortion. This enables a more accurate characterization of the dynamic coupling relationship between key factors, such as topographic and environmental factors, and cumulative deformation, achieving high-precision surface deformation prediction.

The surface deformation prediction method integrating InSAR observation data and neural networks proposed in this embodiment is highly scientific and applicable. This method can not only monitor surface deformation but also utilize driving factors of surface deformation, such as topography and environment, to construct a prediction model, thereby achieving a more complete integrated model for monitoring and prediction. This method is easy to implement and can be widely applied in the fields of monitoring and prediction of geological hazards and engineering deformation.

### Embodiment 2

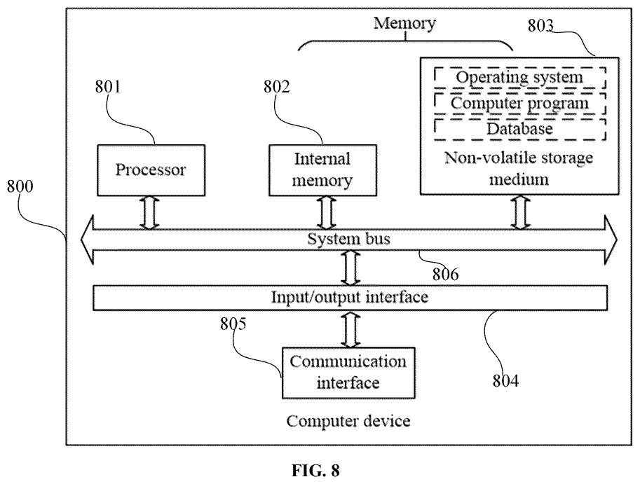

This embodiment provides a computer device. The computer device may be a server or a terminal, and an internal structure thereof may be as shown in FIG. 8. The computer device 800 includes a processor 801, a memory, an input/output (I/O) interface 804, and a communication interface 805. The processor 801, the memory, and the I/O interface 804 are connected through a system bus 806. The communication interface 805 is connected to the system bus 806 through the I/O interface 804. The processor 801 of the computer device 800 is configured to provide computing and control capabilities. The memory of the computer device 800 includes a non-volatile storage medium 803 and an internal memory 802. The non-volatile storage medium 803 stores an operating system, a computer program, and a database. The internal memory 802 provides an environment for operation of the operating system and the computer program in the non-volatile storage medium 803. The database of the computer device 800 is configured to store data in the surface deformation prediction method. The I/O interface 804 of the computer device 800 is configured to exchange information between the processor 801 and an external device. The communication interface 805 of the computer device 800 is configured to communicate with an external terminal through a network. When executed by the processor 801, the computer program implements the surface deformation prediction method in Embodiment 1.

Those skilled in the art may understand that the structure shown in FIG. 8 is only a block diagram of a partial structure related to the solution of the present disclosure and does not constitute a limitation on the computer device to which the solution of the present disclosure is applied. Specifically, the computer device may include more or fewer components than those shown in the figure, or some components may be combined, or a different component arrangement may be used. In an embodiment, a computer device is provided, including a memory and a processor, where the memory stores a computer program, and the computer program is executed by the processor to implement the steps of the above method embodiment.

### Embodiment 3

This embodiment provides a computer-readable storage medium storing a computer program, where the computer program implements the surface deformation prediction method in Embodiment 1 when being executed by a processor.

### Embodiment 4

This embodiment provides a computer program product, including a computer program. The computer program implements the surface deformation prediction method in Embodiment 1 when being executed by a processor.

It is to be noted that the information of a user (including but not limited to device information of the user, personal information of the user and the like) and data (including but not limited to data for analysis, data for storage, data for exhibition and the like) in the present disclosure are information and data authorized by the user or fully authorized by each party, and the information and data are acquired, used and processed according to relevant regulations.

Those of ordinary skill in the art may understand that all or some of the procedures in the method of the foregoing embodiments may be implemented by a computer program instructing related hardware. The computer program may be stored in a nonvolatile computer-readable storage medium. When the computer program is executed, the procedures in the embodiments of the foregoing method may be performed. Any reference to a memory, a database, or other media used in the embodiments of the present application may include a non-volatile and/or volatile memory. The non-volatile memory may include a read-only memory (ROM), a magnetic tape, a floppy disk, a flash memory, an optical memory, a high-density embedded non-volatile memory, a resistive random access memory (ReRAM), a magnetoresistive random access memory (MRAM), a ferroelectric random access memory (FRAM), a phase change memory (PCM), a graphene memory, or the like. The volatile memory may include a random access memory (RAM) or an external cache memory. As an illustration rather than a limitation, the RAM may be in various forms, such as a static random access memory (SRAM) or a dynamic random access memory (DRAM).

The database in the embodiments of the present disclosure may include at least one of a relational database and a non-relational database. The non-relational database may include a distributed database based on a blockchain, but is not limited thereto. The processor in the embodiments of the present disclosure may be a general processor, a central processor, a graphics processor, a digital signal processor (DSP), a programmable logic device, and a data processing logic device based on quantum computing, but is not limited thereto.

The technical characteristics of the above embodiments can be employed in arbitrary combinations. To provide a concise description of these embodiments, all possible combinations of all the technical characteristics of the above embodiments may not be described; however, these combinations of the technical characteristics should be construed as falling within the scope defined by the specification as long as no contradiction occurs.

Several examples are used herein for illustration of the principles and implementations of this application. The description of the foregoing examples is used to help illustrate the method of this application and the core principles thereof. In addition, those of ordinary skill in the art can make various modifications in terms of specific implementations and scope of application in accordance with the teachings of this application. In conclusion, the content of the present specification shall not be construed as a limitation to this application.

What is claimed is:

1. A surface deformation prediction method, comprising:
acquiring target factors in a study area, wherein the target factors are data whose influence degree on a cumulative deformation amount in a future period exceeds an influence degree threshold; the target factors comprise time-series deformation data of historical periods, topographic data of the future period, and environmental data of the future period; the topographic data comprises slope, roughness, and relief, the environmental data comprises vegetation coverage and annual average precipitation; and
based on the target factors, outputting the cumulative deformation amount in the future period using a trained surface deformation prediction model, wherein the surface deformation prediction model is an improved back propagation (BP) neural network; on the basis of a traditional BP neural network, the improved BP neural network is obtained by optimizing weights and bias parameters of the traditional BP neural network by means of a particle swarm optimization (PSO) algorithm and a genetic algorithm (GA).

2. The surface deformation prediction method according to claim 1, wherein a training process for the surface deformation prediction model comprises:
acquiring a sample dataset, wherein the sample dataset comprises historical sample radar image sequences, historical sample topographic time-series data, and historical sample environmental time-series data;
processing the historical sample radar image sequences using remote sensing technology to obtain Interferometric Synthetic Aperture Radar (InSAR) line-of-sight historical time-series deformation data;
processing the InSAR line-of-sight historical time-series deformation data, the historical sample topographic time-series data, and the historical sample environmental time-series data using a discretization method to obtain a preprocessed dataset;
calculating contribution intensities by using the preprocessed dataset as independent variables and a historical cumulative deformation amount as a dependent variable, wherein the historical cumulative deformation amount is a variable value calculated based on the InSAR line-of-sight historical time-series deformation data; the contribution intensities comprise a contribution intensity of each independent variable to the dependent variable and contribution intensities of interactions between the independent variables to the dependent variable; and
training the surface deformation prediction model by using independent variables whose contribution intensities are greater than a contribution intensity threshold as feature data and using the historical cumulative deformation amount as label data.

3. The surface deformation prediction method according to claim 2, wherein the discretization method comprises an equal interval method, a natural breaks method, a quantile method, and a geometric interval method.

4. The surface deformation prediction method according to claim 2, wherein the contribution intensity is represented using a driving force metric value, and a calculation formula for the driving force metric value is as follows:
$$q = 1 - \frac{{\sum }_{h = 1}^{L} {N}_{h} {σ}_{h}^{2}}{N {σ}^{2}} ;$$
wherein q is the driving force metric value; h is the number of stratifications of the independent variable, h=1, 2, . . . , L; N and σ² are a total number of units in the entire study area and a variance of dependent variable values, respectively.

5. The surface deformation prediction method according to claim 1, wherein calculation formulas for the weights are:
$${W}_{1}^{*} = reshape ( {Θ}_{1}^{1 : n . h} , h , n ) ;$$
$${W}_{2}^{*} = reshape ( {Θ}_{3}^{1 : h - o} , o , h ) ;$$
wherein
$${W}_{1}^{*} and {W}_{2}^{*}$$
represent a weight matrix from an input layer to a hidden layer and a weight matrix from the hidden layer to an output layer, respectively; Θ represents a complete set of all parameters; n, h, and o represent the number of nodes in the input layer, the number of nodes in the hidden layer, and the number of nodes in the output layer, respectively; a reshape function represents a function used to organize a parameter vector into a two-dimensional shape of a weight matrix.

6. The surface deformation prediction method according to claim 1, wherein calculation formulas for the bias parameters are:
$${B}_{1}^{*} = {Θ}_{2}^{1 : h} ;$$
$${B}_{2}^{*} = {Θ}_{4}^{1 : o} ;$$
wherein
$${B}_{1}^{*} and {B}_{2}^{*}$$
represent bias vectors for a hidden layer and an output layer, respectively; Θ represents a complete set of all parameters; h and o represent the number of nodes in the hidden layer and the number of nodes in the output layer, respectively.

7. A computer device, comprising: a memory, a processor, and a computer program stored on the memory and executable on the processor, wherein the computer program is executed by the processor to implement the surface deformation prediction method according to claim 1.

8. A non-transitory computer-readable storage medium, wherein the computer-readable storage medium stores a computer program, and when executed by a processor, the computer program implements the surface deformation prediction method according to claim 1.

9. The computer device according to claim 7, wherein a training process for the surface deformation prediction model comprises:
acquiring a sample dataset, wherein the sample dataset comprises historical sample radar image sequences, historical sample topographic time-series data, and historical sample environmental time-series data;
processing the historical sample radar image sequences using remote sensing technology to obtain Interferometric Synthetic Aperture Radar (InSAR) line-of-sight historical time-series deformation data;
processing the InSAR line-of-sight historical time-series deformation data, the historical sample topographic time-series data, and the historical sample environmental time-series data using a discretization method to obtain a preprocessed dataset;
calculating contribution intensities by using the preprocessed dataset as independent variables and a historical cumulative deformation amount as a dependent variable, wherein the historical cumulative deformation amount is a variable value calculated based on the InSAR line-of-sight historical time-series deformation data; the contribution intensities comprise a contribution intensity of each independent variable to the dependent variable and contribution intensities of interactions between the independent variables to the dependent variable; and
training the surface deformation prediction model by using independent variables whose contribution intensities are greater than a contribution intensity threshold as feature data and using the historical cumulative deformation amount as label data.

10. The computer device according to claim 9, wherein the discretization method comprises an equal interval method, a natural breaks method, a quantile method, and a geometric interval method.

11. The computer device according to claim 9, wherein the contribution intensity is represented using a driving force metric value, and a calculation formula for the driving force metric value is as follows:
$$q = 1 - \frac{{\sum }_{h = 1}^{L} {N}_{h} {σ}_{h}^{2}}{N {σ}^{2}} ;$$
wherein q is the driving force metric value; h is the number of stratifications of the independent variable, h=1, 2, . . . , L; N and σ² are a total number of units in the entire study area and a variance of dependent variable values, respectively.

12. The computer device according to claim 7, wherein calculation formulas for the weights are:
$${W}_{1}^{*} = reshape ( {Θ}_{1}^{1 : n . h} , h , n ) ;$$
$${W}_{2}^{*} = reshape ( {Θ}_{3}^{1 : h - o} , o , h ) ;$$
wherein
$${W}_{1}^{*} and {W}_{2}^{*}$$
represents a weight matrix from an input layer to a hidden layer and a weight matrix from the hidden layer to an output layer, respectively; Θ represents a complete set of all parameters; n, h, and o represent the number of nodes in the input layer, the number of nodes in the hidden layer, and the number of nodes in the output layer, respectively; a reshape function represents a function used to organize a parameter vector into a two-dimensional shape of a weight matrix.

13. The computer device according to claim 7, wherein calculation formulas for the bias parameters are:
$${B}_{1}^{*} = {Θ}_{2}^{1 : h} ;$$
$${B}_{2}^{*} = {Θ}_{4}^{1 : o} ;$$
wherein
$${B}_{1}^{*} and {B}_{2}^{*}$$
represent bias vectors for a hidden layer and an output layer, respectively; Θ represents a complete set of all parameters; h and o represent the number of nodes in the hidden layer and the number of nodes in the output layer, respectively.

14. The non-transitory computer-readable storage medium according to claim 8, wherein a training process for the surface deformation prediction model comprises:
acquiring a sample dataset, wherein the sample dataset comprises historical sample radar image sequences, historical sample topographic time-series data, and historical sample environmental time-series data;
processing the historical sample radar image sequences using remote sensing technology to obtain Interferometric Synthetic Aperture Radar (InSAR) line-of-sight historical time-series deformation data;
processing the InSAR line-of-sight historical time-series deformation data, the historical sample topographic time-series data, and the historical sample environmental time-series data using a discretization method to obtain a preprocessed dataset;
calculating contribution intensities by using the preprocessed dataset as independent variables and a historical cumulative deformation amount as a dependent variable, wherein the historical cumulative deformation amount is a variable value calculated based on the InSAR line-of-sight historical time-series deformation data; the contribution intensities comprise a contribution intensity of each independent variable to the dependent variable and contribution intensities of interactions between the independent variables to the dependent variable; and
training the surface deformation prediction model by using independent variables whose contribution intensities are greater than a contribution intensity threshold as feature data and using the historical cumulative deformation amount as label data.

15. The non-transitory computer-readable storage medium according to claim 14, wherein the discretization method comprises an equal interval method, a natural breaks method, a quantile method, and a geometric interval method.

16. The non-transitory computer-readable storage medium according to claim 14, wherein the contribution intensity is represented using a driving force metric value, and a calculation formula for the driving force metric value is as follows:
$$q = 1 - \frac{{\sum }_{h = 1}^{L} {N}_{h} {σ}_{h}^{2}}{N {σ}^{2}} ;$$
wherein q is the driving force metric value; h is the number of stratifications of the independent variable, h=1, 2, . . . , L; N and σ² are a total number of units in the entire study area and a variance of dependent variable values, respectively.

17. The non-transitory computer-readable storage medium according to claim 8, wherein calculation formulas for the weights are:
$${W}_{1}^{*} = reshape ( {Θ}_{1}^{1 : n . h} , h , n )$$
$${W}_{2}^{*} = reshape ( {Θ}_{3}^{1 : h - o} , o , h )$$
wherein
$${W}_{1}^{*} and {W}_{2}^{*}$$
represent a weight matrix from an input layer to a hidden layer and a weight matrix from the hidden layer to an output layer, respectively; Θ represents a complete set of all parameters; n, h, and o represent the number of nodes in the input layer, the number of nodes in the hidden layer, and the number of nodes in the output layer, respectively; a reshape function represents a function used to organize a parameter vector into a two-dimensional shape of a weight matrix.

18. The non-transitory computer-readable storage medium according to claim 8, wherein calculation formulas for the bias parameters are:
$${B}_{1}^{*} = {Θ}_{2}^{1 : h} ;$$
$${B}_{2}^{*} = {Θ}_{4}^{1 : o} ;$$
wherein
$${B}_{1}^{*} and {B}_{2}^{*}$$
represent bias vectors for a hidden layer and an output layer, respectively; Θ represents a complete set of all parameters; h and o represent the number of nodes in the hidden layer and the number of nodes in the output layer, respectively.
